(19) United States
(12) Patent Application Publication
(10) Pub. No.: US 2007/0300107 A1
(43) Pub. Date: Dec. 27, 2007

(54) Device test apparatus

(76) Inventor: Masaaki Shiotani, Tokyo (JP)

Correspondence Address: NIXON PEABODY, LLP, 401 9TH STREET, NW, SUITE 900, WASHINGTON, DC, 20004-2128, US

(21) Appl. No.: 11/798,635

(22) Filed: May 15, 2007

(30) Foreign Application Priority Data
Jun. 13, 2006 (JP) 2006-163576

(51) Int. Cl. G01R 31/28

(52) U.S. Cl. 714/724

(57) ABSTRACT

The present invention provides a device test apparatus for testing an integrated device circuit having a plurality of combinational circuits and multi-wiring-layers interconnecting the combinational circuits. The device test apparatus includes a plurality of scanning flip-flop (FF) circuits corresponding to the combinational circuits and the multi-wiring-layers. The FF circuits supply respective test data to the combinational circuits and the multi-wiring-layers and receive respective test resultant data generated from the combinational circuits and the multi-wiring-layers. The device test apparatus can test not only logical operations of combination circuits but also electrical connections across the combination circuits, thus improving reliability of the integrated circuit device.

### BACKGROUND OF THE INVENTION

1. Field of the Invention

The present invention relates to a device test apparatus for testing an integrated circuit device.

2. Description of the Related Art

A conventional device test apparatus is described in, for example, Japanese Patent Application Laid-Open Publication No. H05-53862 (document D1) and Japanese Patent Application Laid-Open Publication No. H06-148293 (document D2). FIG. 1A is a schematic circuit diagram showing a device test apparatus disclosed in document D1. FIG. 1B is a schematic circuit diagram showing a device test apparatus disclosed in document D2.

As shown in FIG. 1B, the device test apparatus for assessing a change of a scan path length includes a test processor 1, a test control unit 3 connected to the test processor 1, and a main processor 2 having a scan path. The test control unit 3 has a temporary memory means 3a configured by the number of flip-flop (FF) circuits n (=7), a select circuit 3c, and a selection FF circuit 3b. The seven FF circuits of the temporary memory means 3a are connected in series. The temporary memory means 3 receives an input scan path signal Din from the test processor 1 via a first FF circuit. The select circuit 3c selectively scans in either of one of the scan path signal or one of signals held in the seven FF circuits. The scan-in signal of the select circuit 3c is supplied to the main processor 2. The selection FF circuit 3b holds a selection signal SEL supplied to the select circuit 3c.

Each of the FF circuits of the temporary memory means 3a has a set terminal S, a data input terminal D, a data output terminal Q, and a clock signal input terminal (not shown). In response to a high level (“H”) signal supplied to the set terminal S, each of the FF circuit receives a signal supplied to the data input terminal D thereof in synchronization with a clock signal supplied to the clock signal input terminal thereof (not shown).

If the number of total bits of the scan path of the main processor 2 is, for example, 795 bits, five bits are insufficient so that the scan path has 800 bits. The test processor 1 sets a value of five to the selection FF circuit 3b. The selection FF circuit 3b sends the selection signal SEL to the select circuit 3c so that the select circuit 3c individually inputs signals supplied from the first and fifth FF circuits of the temporary memory means 3a. Thus, five bits are added to the scan path signal Din by supplying one bit to each of five FF circuits of the temporary memory means 3a. Therefore, the main processor 2 outputs a signal having the number of 800 bits which is an integral multiple of 8 bits. When a signal configured by data having parities, each data having eight bits, is sent, insufficient dummy bits can be appropriately compensated.

In FIG. 1B, the circuit diagram of the device test apparatus disclosed in document D2 is schematically illustrated. The device test apparatus of FIG. 1B tests a logic circuit 6 and specifies the maximum operating frequency (the maximum delay time) of the logical circuit and the maximum delay path without a special test instrument. In the test circuit, input signals Y1 to Yi supplied to the logical circuit 6 are respectively held at FF circuits 4. In synchronization with a start clock signal CKS, the input signals Y1 to Yi are supplied to the logical circuit 6 via start gate circuits 5. Output signals W1 to Wj of the logical circuit 6 are respectively supplied to FF circuits 7 in synchronization with an end clock signal CKE. The start clock signal CKS and the end clock signal CKE are generated at a predetermined timing by a clock signal controlling circuit 8. Therefore, the delay time of the test circuit 6 are specified on the ground of a time interval from the start clock signal CKS to the end clock signal CKE.

Each of the test circuits disclosed in documents D1 and D2 tests one combinational circuit where a plurality of logic gates are combined. If an integrated circuit having a larger size is designed, combinational circuits in the integrated circuit are necessarily interconnected by longer signal wires. Thus, it is more difficult to interconnect the combinational circuits by one signal wiring-layer. For this reason, the combinational circuits are usually interconnected by multi wiring-layers having a plurality of signal wiring-layer via through-holes and via holes. In the conventional device test apparatuses, such multi wiring-layers can not be tested distinctly from the combinational circuits. When the conventional device test apparatuses detect defective points, it is difficult to specify whether the combination circuits or interconnection parts for interconnecting the combination circuits are defective.

In particular, transistors integrated in the combinational circuit are disposed and interconnected under various conditions. The disposition and interconnection pattern of the transistors are designed by utilizing thick wires and a plurality of electric contacts in a view of improvement of reliabilities of the device test apparatus. Thus, it is understood that a failure rate of the combinational circuit is extremely low. On the other hands, signal wires interconnecting combinational circuits are differently designed depending upon circuit structures of integrated circuits. In an integrated circuit having a large dimension, areas of the integrated circuit are largely occupied by signal wires. Thus, for example, thinner signal wires are utilized for interconnecting combinational circuits and only one electric contact part is formed for interconnecting wiring-layers of a multi-wiring layer. Therefore, failure rates of such signal wiring parts are high in comparison with the combinational circuit.

FIG. 2 is a cross-sectional view showing a contact part of a typical semiconductor device. The typical semiconductor device includes a silicon substrate into which a plurality of transistors are formed, a first wiring-layer, and a second wiring-layer. The first wiring-layer is formed above the silicon substrate via a first insulating film. The second wiring-layer is formed above the first wiring-layer via a second insulating film. One of the plurality of transistors is electrically connected to the first wiring-layer by a first contact layer with which a through-hole formed in the first insulating film is filled. The first wiring-layer is electrically connected to the second wiring-layer by a second contact layer with which a through-hole formed in the second insulating film is filled.

The first and second contact layers are typically formed from thermo stable metal such as tungsten (W). The first and second wiring-layers are typically formed from a low resistive metal such as aluminum (Al), copper (Cu), and other highly conductive material. These metals for the wiring-layers are not thermally stable.

Although the first contact layer formed on the silicon substrate can be heat-treated under an optimal condition so that an interface between them has a low resistance, the second contact layer formed after forming the first wiring-layer can not be sufficiently heat-treated at high temperature. This is because an excessive heat-treatment of the first wiring-layer strongly influences the first wiring-layer which is not thermally stable. Therefore, in the second contact layer connecting between the first and second wiring-layers, resistances of interfaces between the second contact layer and the first wiring-layer and between the first contact layer and the first wiring-layer can not be sufficiently decreased, which results in low conductivity and high failure rate of the integrated circuit device.

### SUMMARY OF THE INVENTION

An object of the present invention is to provide a device test apparatus which can test logical operations of combination circuits and electric connections across the combinational circuits.

According to a first aspect of the present invention, there is provided a device test apparatus for testing a plurality of test object circuit blocks arrayed in sequence as a plurality of stages. The device test apparatus comprises a plurality of unit bit relay circuits respectively corresponding to the test object circuit blocks. Each of the unit bit relay circuits has a mode switching terminal, a data input terminal, a scan input terminal, and a trigger input terminal. Each of the unit bit relay circuits selectively receives an input unit bit supplied to the data input terminal or the scan input terminal in response to a mode switching signal supplied to the mode switching terminal, holds the input unit bit, and relays the input unit bit to each of the test object circuit blocks in response to a trigger input signal supplied to the trigger input terminal. The device test apparatus further comprises an input gate circuit for receiving a test data unit bit by unit bit in response to the trigger input signal and for sending the test data to an upper stage of the plurality of test object circuit blocks. The device test apparatus further comprises a trigger part for supplying the trigger input signal to the trigger input terminals of the unit bit relay circuits at substantially the same time. The device test apparatus further comprises a mode switching part for supplying the mode switching signal to the mode switching terminals of the unit bit relay circuits at substantially the same time. The data input terminal and the scan input terminal of the unit bit relay circuit corresponding to one of stages are respectively connected to an output terminal and an input terminal of the test object circuit block corresponding to the one of stages. An output terminal of the unit bit relay circuit corresponding to the one of stages is connected to an input terminal of the test object circuit block corresponding to the next one of stages. The test object circuit blocks and the unit bit relay circuits are integrally formed in an IC chip.

The device test apparatus can test not only logical operations of combination circuits but also electrical connections across the combination circuits, thus improving reliability of an integrated circuit device.

### BRIEF DESCRIPTION OF THE DRAWINGS

FIG. 1A is a schematic block diagram showing a conventional device test apparatus;

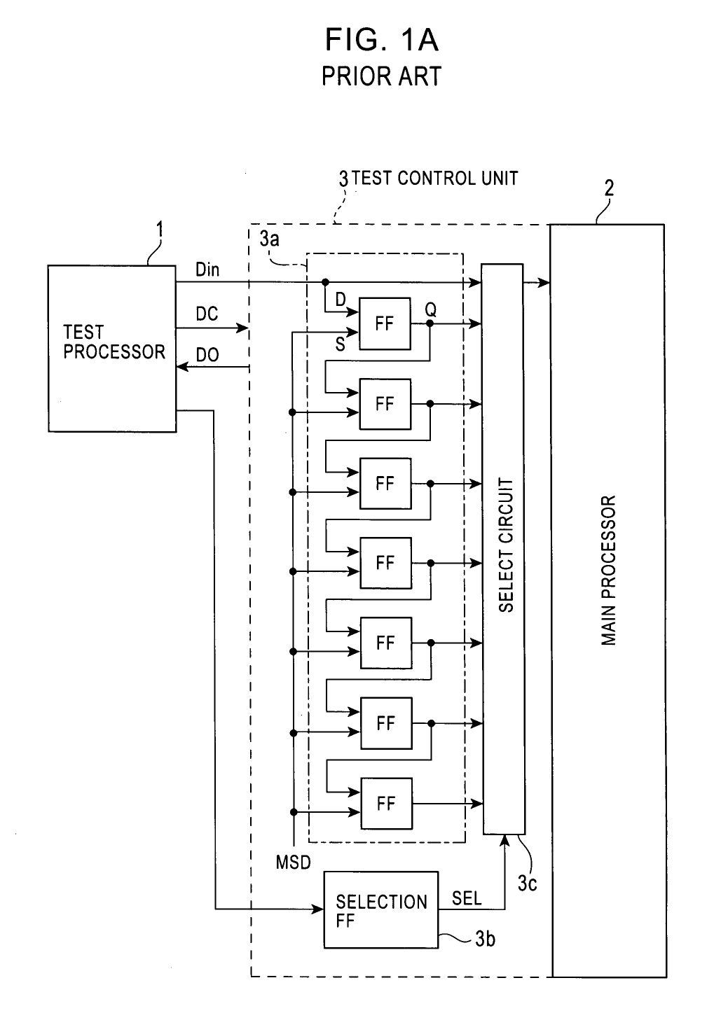

FIG. 1B is a schematic block diagram showing a conventional device test apparatus;

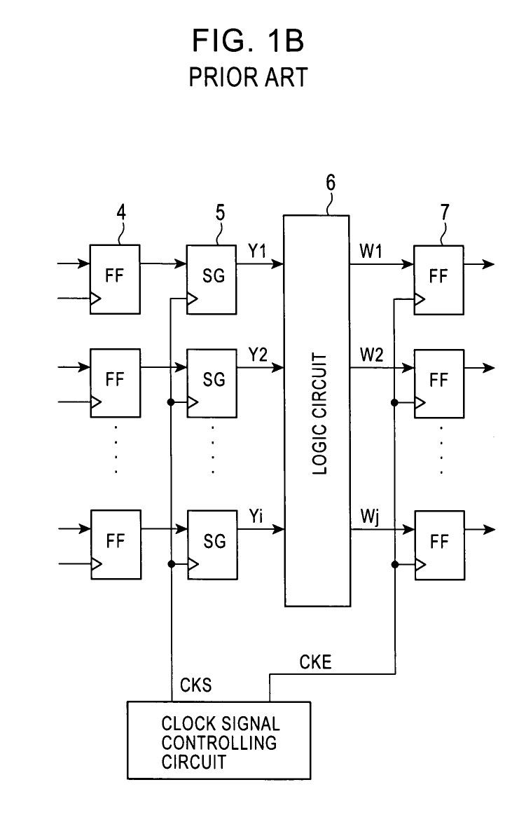

FIG. 2 is a cross-sectional view showing contact layers of a conventional semiconductor device;

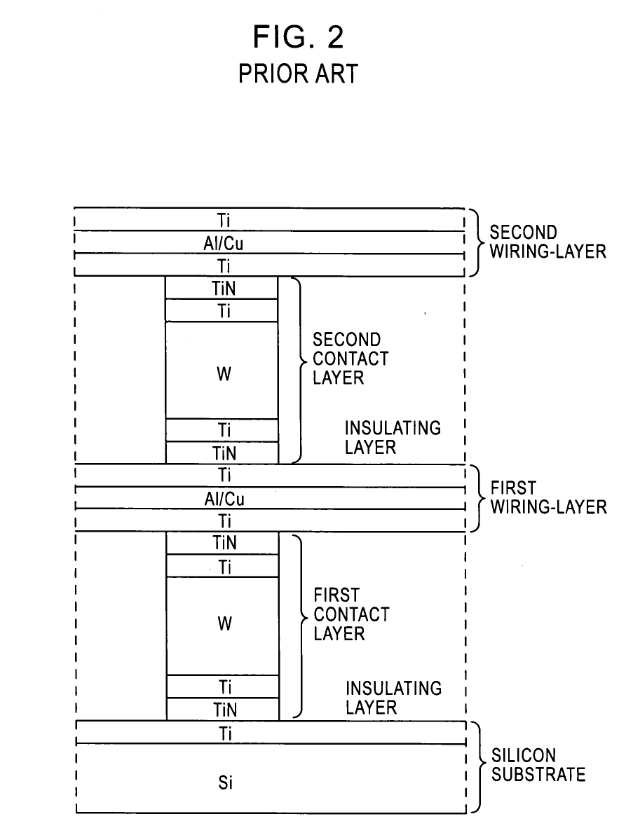

FIG. 3 is a schematic block diagram showing an embodiment of the device test apparatus according to the present invention; and

FIG. 4 is a schematic circuit diagram showing a scan testing flip flop circuit of the embodiment.

### DETAILED DESCRIPTION OF THE INVENTION

The following is a detailed description of a preferred embodiment of the test circuit according to the present invention in reference to drawings. It should be however noted that the present invention is not limited to the following descriptions and the embodiment described in reference to the drawings.

The embodiment of the device test apparatus according to the present invention tests performance of an integrated circuit device. The integrated circuit device is configured by two combinational circuits and a multi-wiring-layer connecting the two combinational circuits. The combinational circuits and the multi-wiring-layer are formed in the same semiconductor chip. The multi-wiring-layer includes signal wires, signal wiring-layers, and interconnecting parts interconnecting the signal wiring-layers, one of which electrically connects across the two combinational circuits. In the embodiment, logical operations of the two combinational circuits and the multi-wiring-layer interconnecting the two combinational circuits are examined.

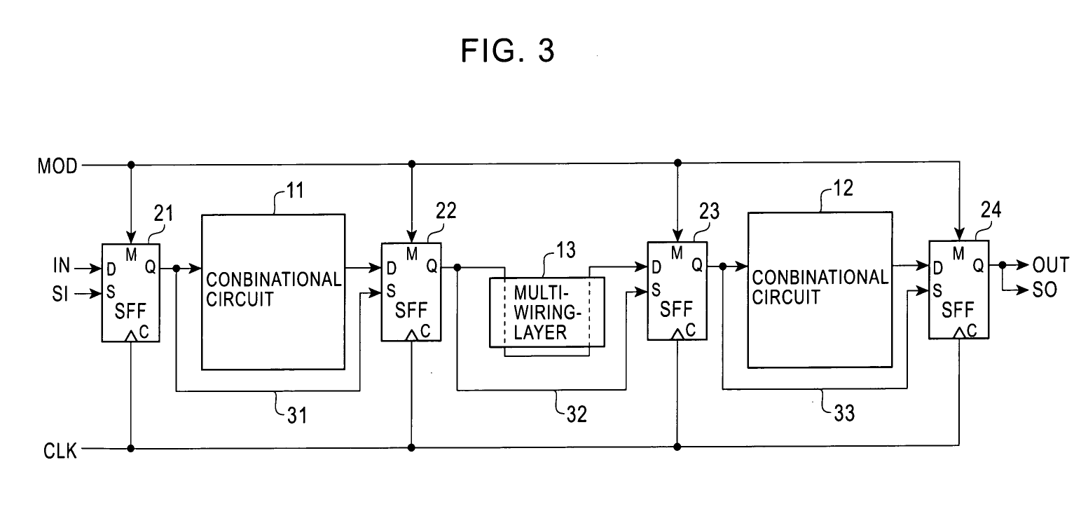

FIG. 3 is a schematic block diagram showing the embodiment of the device test apparatus according to the present invention. The embodiment is capable of testing combinational circuits 11 and 12 and a multi-wiring-layer 13 electrically connected across the circuits 11 and 12, thus identifying defective parts. Each of the combinational circuits 11 and 12 performs a logic operation in response to an input signal supplied to an input terminal thereof, and outputs a logical resultant signal corresponding to the logic operation from an output terminal thereof.

The device test apparatus includes three scan testing flip-flop (hereafter “SFF”) circuits 21, 22, and 23, each having a data input terminal D, a scanning input terminal S, a clock terminal C, a mode switching terminal M, and an output terminal Q. The input terminal of the combinational circuit 11 is connected to the output terminal of the SFF circuit 21. The output terminal, of the combinational circuit 11 is connected to an input terminal of the multi-wiring-layer 13 via the SFF circuit 22. An output terminal of the multi-wiring-layer 13 is connected to the input terminal of combinational circuit 12 via the SFF circuit 23. SFF circuit 24 is connected to the output terminal of the combinational circuit 12.

The SFF circuits 21 to 24 similarly operate at two operation modes in response to a signal. In a normal operation mode which is switched by a mode signal (having a “L” in level) supplied to a mode switching terminal M, each of the SFF circuits 21 to 24 receives a signal given to the data input terminal D thereof in synchronization with a leading edge of a clock signal given to the clock terminal thereof, and holds the signal. And then, each of the SFF circuits 21 to 24 outputs the signal from output terminal thereof in synchronization with a trailing edge of the clock signal. In a scanning test mode which is switched by a mode signal (having a high level “H”) supplied to a mode switching terminal M, each of the SFF circuits 21 to 24 receives a signal given to the scanning input terminal S thereof in synchronization with a leading edge of a clock signal, and holds the signal. And then, each of the SFFs 21 to 24 outputs the signal from output terminal thereof in synchronization with a trailing edge of the clock signal.

The SFF 21 circuit of a first stage receives an input signal supplied to the combinational circuit 11 and a scan input signal SI which is a test signal supplied from a test instrument (not shown) to the scanning input terminal S thereof. The output terminal Q of the SFF circuit 21 is connected to the input terminal of combinational circuit 11 and connected to the scanning input terminal S of the SFF circuit 22 via a scanning path 31.

The data input terminal D of the SFF circuit 22 is connected to the output terminal of the combinational circuit 11. The output terminal Q of the SFF circuit 22 is connected to one end of the multi-wiring-layer 13 and connected to the scanning input signal S of the SFF circuit 23 via a scan path 32. The data input terminal D of the SFF circuit 23 is connected to the other end of the multi-wiring-layer 13. The output terminal Q of the SFF circuit 23 is connected to the input terminal of the combinational circuit 12 and connected to the scanning input terminal S of the SFF circuit 24 via a scan path 33. The data input terminal D of the SFF circuit 24 is connected to the output terminal of the combinational circuit 12. Logical test resultant signals produced by the combinational circuits 11, 12 and test resultant signal of the multi-wiring-layer 13 are supplied from the output terminal Q of the SFF circuit 24 as a scan output signal SO.

Each of the SFF circuits 21 to 24 receives the mode signal MOD supplied to the mode switching terminal M thereof and the clock signal CLK supplied to the clock terminal C thereof. The clock signal CLK is supplied from a clock signal generation circuit (not shown) to the SFF circuits 21 to 24 at the substantially same time. The mode signal MOD is supplied from a mode signal generation circuit (not shown) to the SFF circuits 21 to 24 at substantially the same time.

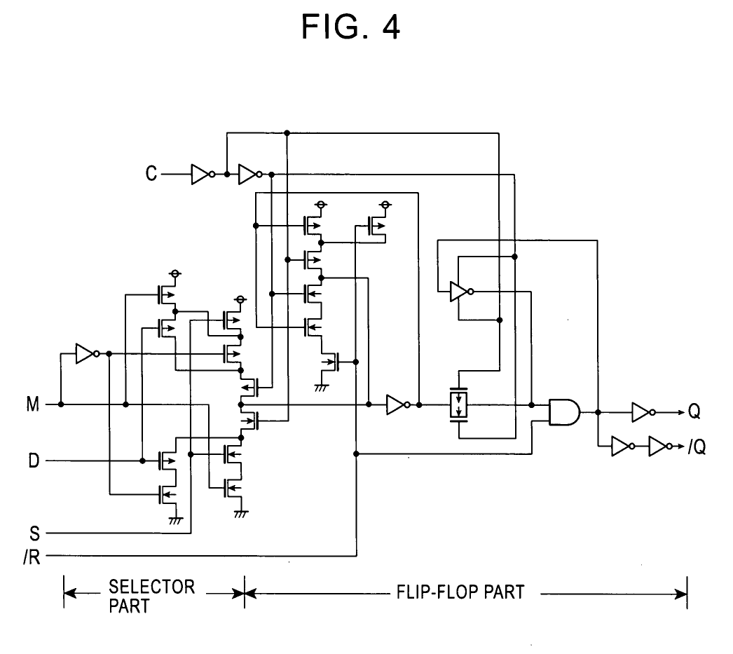

FIG. 4 is a schematic circuit diagram showing the SFF circuit of the device test apparatus shown in FIG. 3. The SFF circuit has a selector part and a flip-flop part connected to the selector part. The selector part receives a signal given to the data input terminal D thereof or a signal given to the scanning input terminal S in response to a mode signal MOD supplied to the mode switching terminal thereof. The flip-flop part holds the signal sent from the selector part in synchronization with the clock signal given to the clock terminal C thereof and then outputs the signal in synchronization with the clock signal. From output terminals Q and /Q of the flip-flop part, a complementary output signal is sent. Thus, each of the SFF circuits performs a switching operation in accordance with the mode signal MOD.

The operation modes of the embodiment will now be described.

(1) Normal Operation Mode

Each of the SFF circuits 21 to 24 receives a low (“L”) level mode signal MOD given to a mode switching terminal thereof, thus switching to the normal operation mode. In the normal operation mode, each of the SFF circuits 21 to 24 receives a signal supplied to the date input terminal D thereof in synchronization with a leading edge of a clock signal CLK supplied to the clock terminal C thereof and holds the data. Each of the SFF circuits 21 to 24 outputs the signal from the output terminal Q thereof in synchronization with a trailing edge of the clock signal CLK. Thus, the SFF circuits 21 to 23 supply the signals to the combinational circuit 11, the multi-wiring-layer 13, and the combinational circuit 12, respectively, in synchronization with the trailing edge of the clock signal CLK. The combinational circuits 11 and 12 respectively perform logical operations and respectively output logical test resultant signals to the SFF circuits 22 and 24 as output signals. The multi-wiring-layer 13 outputs a test resultant signal to the SFF circuit 23 as an output signal. The SFF circuits 22 to 24 respectively receive the output signals of the combinational circuit 11, the multi-wiring-layer 13, and the combinational circuit 12 in synchronization with a leading edge of a subsequent clock signal CLK. Each of the SFF circuits 21 to 24 operates as a normal FF for adjusting timing of signals.

(2) Scanning Test Mode

Each of the SFF circuits 21 to 24 receives a high (“H”) level mode signal MOD supplied to the mode switching terminal thereof, thus switching to the scanning test mode. In the scanning test mode, each of the SFF circuits 21 to 24 receives a signal supplied to the scan input terminal S thereof in synchronization with a leading edge of a clock signal CLK supplied to the clock terminal and holds the signal. Each of the SFF circuits 21 to 24 outputs the signal from the output terminal Q thereof in synchronization with a trailing edge of the clock signal CLK. In the scanning test mode, a shift register having three stages is configured by the four SFF circuits 21 to 24 connected in series via the scan paths 31 to 33. The shift register inputs the scan input signal SI and outputs the scan output signal SO. Output signals of the three stages are respectively supplied to the combinational circuit 11, the multi-wiring-layer 13, and the combinational circuit 12.

The integrated circuit device including the test circuit of FIG. 3 can be tested by utilizing the SFF circuits 21 to 24 as buffer circuits for inputting test signal and outputting resultant test signal. The normal operation mode and scan test mode of the SFF circuits 21 to 24 can be selectively switched to each other by sending the mode signal to the SFF circuits. A test operation of the embodiment is performed in the following way.

The operation modes are switched to the scan test mode, and thus the scan input terminals S are selected as input terminals. The shift register is configured by the four SFF circuits 21 to 24 via the scan path 31 to 33. The SFF 21 sequentially receives input binary data (a1, a2, a3) as a scan input signal SI in synchronization with a clock signal CLK. The sequential input binary data (a1, a2, a3) are respectively supplied to the SFF circuits 21 to 23 passing through the scan path 31 to 32 in synchronization with the clock signal and then held at SFF circuits 21 to 23, respectively. The SFF circuit 23 holds the binary datum al as a test datum for the combinational circuit 12. The SFF 22 circuit holds the binary datum a2 as a test datum for the multi-wiring-layer 13. The SFF 21 holds the binary datum a3 as a test datum of combinational circuit 11. In synchronization with the clock signal, the binary data a1, a2, a3 are supplied to the combinational circuit 12, the multi-wiring-layer 13, and the combinational circuit 11, respectively. The combinational circuit 12, the multi-wiring-layer 13, and combinational circuit 11 operate and output binary data b3, b2, b1 as test resultant signals, respectively.

The operation modes are subsequently switched to the normal operation mode. In response to one pulse of the clock signal, the output binary data b3, b2, b1 are held at the SFF circuits 24 to 22, respectively.

The operation mode is subsequently switched back to the scan test mode. The output binary data b3, b2, b1 respectively held at the SFF circuit 24 to 22, which are respectively test resultant data of the combinational circuit 12, the multi-wiring-layer 13, and the combinational circuit 11, are supplied from the output terminal Q of the SFF circuit 24 in sequence as a scan output signal SO.

The actually observed scan output signal SO are compared to expected value of the combinational circuit 11, 12 and the multi-wiring-layer 13. Therefore, individual tests as to whether or not combinational circuits 11, 12 and the multi-wiring-layer 13, which configure the integrated device circuit, can be respectively performed to test expected operations.

As mentioned above, the embodiment of the device test apparatus according to the present invention can test the combinational circuits and additionally the signal-wire connecting across the combinational circuits. Defectives not only in the combinational circuits but also the signal-wire electrically connecting across the circuits can be detected. The device test apparatus according to the present invention is not limited to the above described embodiment. The embodiment can be modified as follows.

(a) The number of the combinational circuits and the number of the signal-wires are not limited to those of FIG. 3.

(b) The test object circuit blocks are not limited to combinational circuits and the multi-wiring-layer. An electric connection of a long and thin signal wire may be tested. A multi-wiring-layer having a plurality of interlayer interconnecting parts may be divided into several parts as test objects.

This application is based on Japanese Patent Application No. 2006-163576 which is herein incorporated by reference.

What is claimed is:

1. A device test apparatus for testing a plurality of test object circuit blocks arrayed in sequence as a plurality of stages comprising:
a plurality of unit bit relay circuits respectively corresponding to said test object circuit blocks, each of said unit bit relay circuits having a mode switching terminal, a data input terminal, a scan input terminal, and a trigger input terminal, each of said unit bit relay circuits selectively receiving an input unit bit supplied to said data input terminal or said scan input terminal in response to a mode switching signal supplied to said mode switching terminal, holding said input unit bit, and relaying said input unit bit to each of said test object circuit blocks in response to a trigger input signal supplied to said trigger input terminal;
an input gate circuit for receiving a test data unit bit by unit bit in response to said trigger input signal and sending said test data to an upper stage of said test object circuit blocks;
a trigger part for supplying said trigger input signal to said trigger input terminals of said unit bit relay circuits at substantially the same time; and
a mode switching part for supplying said mode switching signal to said mode switching terminals of said unit bit relay circuits at substantially the same time;
wherein
said data input terminal and said scan input terminal of said unit bit relay circuit corresponding to one of stages are respectively connected to an output terminal and an input terminal of said test object circuit block corresponding to said one of stages, and
an output terminal of said unit bit relay circuit corresponding to said one of stages is connected to an input terminal of said test object circuit block corresponding to the next one of stages.

2. A device test apparatus according to claim 1, wherein
said test object circuit blocks and said unit bit relay circuits are integrally formed in an IC chip.

3. A device test apparatus according to claim 2, wherein
said test object circuit block is a combinational circuit in which a plurality of logic circuits are combined or a multi-wiring-layer interconnecting said combinational circuits.

4. A device test apparatus according to claim 2, wherein
said unit bit relay circuit includes a D-flip flop circuit and a two-input switching and relaying switch connected to said D-flip flop circuit, so as to perform a switching operation in accordance with said mode switching signal.
